(19) United States
(12) Patent Application Publication
(10) Pub. No.: US 2006/0052065 A1
(43) Pub. Date: Mar. 9, 2006

(54) Transmit diversity fo base stations

(76) Inventors: Gideon Argaman, Kiryat-Tivon (IL); Paul Lemson, Woodinville, WA (US); Shmuel Miller, Oshrat (IL); Joseph Shapira, Haifa (IL)

Correspondence Address: Anthony Castorina, Suite 207, 2001 Jefferson Davis Highway, Arlington, VA, 22202, US

(21) Appl. No.: 10/516,318

(22) PCT Filed: Jun. 12, 2003
(86) PCT No.: PCT/IL03/00506

§ 371 Date: Dec. 13, 2004

Related U.S. Application Data
(60) Provisional application No. 60/388,320, filed on Jun. 14, 2002.

(51) Int. Cl. H04B 1/02; H04B 7/02; H03C 7/02; H04M 1/00

(52) U.S. Cl. 455/101; 455/91; 455/562.1

(57) ABSTRACT

A method and corresponding upgrade kit, for enhancing a base station (10) having a CDMA air interface and a passive antenna (12) with receive space diversity capability so as to provide the base station with transmit diversity capability. The method comprises attaching a radio frequency interface unit to an R.F. output of the base station to obtain a sample of a main R.F. signal, attaching a diversity unit (20) to the radio frequency interface unit to generate a transmit diversity signal, and connecting the diversity unit to the passive antenna to transmit the transmit diversity signal.

### FIELD AND BACKGROUND OF TH INVENTION

The present invention relates to a method, system and apparatus for providing cellular base stations and the like with transmit diversity and, more particularly, but not exclusively to a method, system and apparatus which is readily applicable as an upgrade to existing base stations.

Many currently installed cellular base stations include the capability to transmit and receive using multiple air interfaces, air interfaces being radio transmission signal formats used in wireless multiple access networks. Examples of such air interfaces, which are defined in cellular industry standards, include AMPS (Advanced Mobile Phone System, involving an analog FM signal employing a 30 kHz channel), CDPD (cellular digital packet data employing a 30 kHz channel), and CDMA (code division multiple access employing a 1.25 MHz channel).

Many cellular base stations likewise have the capability to simultaneously receive multiple air interface signals. Furthermore, a cellular base station is typically capable of receiving and demodulating multiple signals of a single air interface type.

Cellular base stations typically employ a receive diversity capability, which employs two separate antennas or two separate sets of antenna elements for reception of radio signals from mobile or fixed subscriber units. An example of such an advanced cellular base station is that employed in cellular CDMA networks.

A number of techniques are available to enhance base station performance in terms of the number of mobile units that can be supported by a single base station or the available bandwidth per mobile station. One of these techniques is transmit diversity, that is the use of two antennas at the transmitting end to transmit versions of the same signal. The receiving device is able to use the difference between the two signals to overcome fade and the like and thus is able to obtain the same signal for less overall transmit resources. Urban environments in particular need diversity to combat their slow speed and to overcome cases where fading is flat.

Currently, base stations are constructed with antenna arrangements that physically allow for transmit diversity, that is to say two or more antennas are generally available, or single composite antennas. This is because for many years, base stations have been constructed to support receive diversity, and in particular the ability to receive a signal from the mobile unit at displaced locations in order to overcome multipath errors, fades and the like, so-called space diversity.

Existing cellular base stations could benefit materially, in terms of Forward, that is base station to mobile, link performance, from the addition of such transmit diversity. Transmit diversity typically employs two separate antennas or two separate sets of antenna elements for transmission of signals from a base station to mobile or fixed subscriber units. Transmit diversity enabled base stations employ signal processing for generating a diversity signal, which are typically implemented using a suitable transformer a different code or a different modulation. The transform operates on a main transmission signal to be radiated from a first or Main transmit antenna, and obtains a second or Diversity transmission signal, which can then be transmitted from the second or Diversity transmit antenna. In order to benefit from the transmit diversity capability, mobile or fixed subscriber units must have a capability to process the two separate Forward Link signals appropriately. Without such processing there may not be any net performance benefit under certain conditions e.g., slow-moving or stationary subscriber units.

It is customary that each base station location, known as a Cell Site, is equipped for multiple separate coverage zones or Sectors, where each sector covers a certain azimuthal range. A typical Cell Site may typically host three such sectors. In such a case, three separate sets of directional antennas are needed to provide coverage.

In a case where a Receive diversity capability is provided for each Sector, two receive antennas per sector or two sets of receive antenna elements per sector are provided. When it is desired to add a capability for Transmit diversity for each Sector, two transmit antennas per sector or two sets of transmit antenna elements per sector are provided. If the use of two separate transmit antennas and two separate receive antennas per Sector are being contemplated, however, planning difficulties can arise. In certain urban or suburban applications there are zoning or other regulatory restrictions which prevent deployment of more than a certain quantity of antennas per cell site, or alternatively a maximum overall size of the electromagnetic radiating structure may be specified by local ordinances.

In a case where local ordinances permit the deployment of only one radiating structure or one radome-covered structure per Sector, it is necessary to employ innovative approaches to obtain the desired radio system performance while simultaneously complying with local ordinances. One such approach known in the art is to employ a single antenna for both transmit and receive along with a suitable filter network known as a Duplexer. The Duplexer feeds signals from the transmit and receive sections of a base station to a single antenna. In the event that Diversity transmit and receive capabilities are needed, a second antenna fed by a Duplexer may be used, or alternatively an antenna with two sets of dual-slant cross-polarized antenna elements within a single radome may be employed. In that case, the +45 degree elements may be used for the first or Main transmit and receive functions while the −45 degree elements may be used for the second or Diversity transmit and receive functions.

However, despite the availability of a duplexer, and despite most base stations having the necessary second antenna, conversion of the existing base stations to support transmit diversity is a complicated operation. To carry out the conversion, it is necessary to split the baseband signal before it is modulated onto the carrier frequency, introduce a delay or transform or like factor such as use of a different code or a slight frequency shift, into one of the signals and then separately modulate the two baseband signals for r.f. transmission. Such a conversion entails entering the base station itself and carrying out far from trivial modifications to components that can be difficult to access. Entry into the base station unit itself may void warranties or otherwise reduce the responsibility levels of the manufacturer and modifications to the internal connections may be a cause of concern to the operator. In addition, each modification must be applied separately to each carrier frequency allocation. Entry into the base station is necessary because base stations do not usually provide an external baseband connection. In addition a second r.f. modulator may be required which is expensive and wasteful of resources.

The present detailed description hereby expressly incorporates by reference in their entireties U.S. patent application Ser. Nos. 09/697,770, 60/161,918, 60/177,653, 60/330,505, and 60/342,105, belonging to the present applicant. These previously filed applications disclose antenna array systems which implement transmit diversity capability and additional base station transmission and reception capabilities. Certain of the embodiments in the above-incorporated U.S. patent applications use active antenna array systems. Some cellular network applications do not permit the use of active antenna array systems, or at least render such use of little or no advantage. The power amplifiers for transmission, and also the Low Noise Receive amplifiers, may be located near the antenna, but in some cases there is no advantage in this either. An example of such a cellular network application is where a sufficiently low radio transmission tower is employed by the cellular network, so that RF cable losses are not significant. Another example is where the distance between the antenna(s) and the radio base station is very short, and where the antennas are deployed nearby on a rooftop. In such a case, RF cable losses may not be significant and use of an active antenna array system may neither be required nor desirable. In such cases, it may be advantageous to instead locate all the transmit and receive amplifiers, RF transmit and receive filters, etc. within or nearby the radio base station. Another such example is where very high composite power is required to be transmitted and special transmit amplifier cooling arrangements are required, which may not be suitable for tower-mounted or roof-mounted active antenna array applications.

Certain of the above-incorporated U.S. patent applications include descriptions of embodiments providing transmit diversity capability for CDMA base stations. These embodiments employ various signal processing means to generate or synthesize the second or Diversity transmit signal, such as time delay and/or phase sweep transforms. Existing base station antenna arrangements typically utilize receive space diversity antennas, e.g., to combat the adverse effects of multipath propagation. A prevailing cellular base station configuration incorporates a space diversity antenna pair in each sector.

As explained above, transmit diversity can provide enhanced capacity and/or coverage for CDMA networks. An upgrade is desired in many of these cases in order to enhance the capacity for a particular sector by adding transmit diversity. The benefit to the sector of the enhanced capacity can range from 20% to 200%. The issue remains however, of how to apply such a feature easily and cheaply to an existing base station where access to the baseband signal is not easily available.

One approach known in the art provides simultaneous transmission of multiple air interface signals. The approach employs low-power combining at baseband frequencies, Intermediate Frequencies (IF) or Radio Frequencies (RF). In such cases, and wherever significant RF transmit power is required, a multicarrier linear power amplifier (MCPA) may be employed. A composite low-power signal consisting of multiple signal components representing various air interfaces is amplified by the MCPA, then filtered appropriately and radiated by the base station antenna. In such a case transmit diversity must be applied before combining the signals.

There is thus a widely recognized need for, and it would be highly advantageous to have, a way of upgrading existing base stations for transmit diversity devoid of the above limitations.

### SUMMARY OF THE INVENTION

According to one aspect of the present invention there is provided upgrading apparatus for obtaining a transmit diversity signal for transmission alongside a main R.F signal using at least one antenna, the apparatus comprising:
an R.F. operable signal extractor for extracting a sample of said R.F. main signal, and
an R.F. operable diversity unit for transforming said R.F. sample signal thereby to form said transmit diversity signal, said apparatus being configured for insertion between at least one R.F. output of an existing cellular base station and a passive diversity antenna, said main R.F. signal being obtained from said R.F. output, thereby to confer upon said existing cellular base station a transmit diversity capability.

Preferably, said existing base station comprises a single R.F. output for transmit signals and at least two R.F. inputs for receive signals.

Preferably, said single R.F. output is a low power output, said apparatus further comprising amplification.

Preferably, said R.F. signal is a low power R.F. signal and said apparatus further comprises amplification circuitry for amplifying said main and said diversity signals.

Preferably, said R.F. signal is a high power R.F. signal.

Preferably, said base station comprises two receive/transmit subsystems, each for transmitting and receiving separate channels.

Preferably, said diversity antenna is for adding to said base station as part of said upgrading.

Preferably, said apparatus comprises two co-located antennas for substituting with said at least one antenna.

Preferably, said apparatus comprises two co-located antenna parts for substituting with said at least one antenna wherein said antenna parts form at least one of a group comprising a two-column antenna and a dual polarized antenna.

Preferably, said passive antenna comprises at least two antenna elements, thereby to provide receive space diversity capability.

Preferably, said cellular base station comprises a CDMA air interface, and wherein said main signal and said diversity signal comprise multiple CDMA carriers.

Preferably, said signal extractor is located in proximity to said R.F. output.

Preferably, said signal extractor is located within a housing configured for connection in proximity to said base station.

Preferably, said R.F. signal is a low power R.F. signal, said apparatus further comprises amplification circuitry for amplifying said main and said diversity signals, and said amplification circuitry is located in proximity to the respective antennas.

Preferably, said amplification circuitry is located within a housing unit configured for connection in proximity to said passive antenna.

Preferably, said housing unit is a modular unit comprising a first module for a main signal path and a second module for a diversity signal path.

Preferably, said cellular base station comprises a plurality of outputs and said signal extractor comprises a signal combiner, said sample comprising a combination of signals from said outputs.

Preferably, said signal extractor comprises at least one directional coupler.

Preferably, said base station comprises a plurality of R.F. outputs and said signal extractor comprises a plurality of directional couplers.

Preferably, said base station comprises a plurality of R.F. outputs, and said signal extractor comprises a plurality of directional couplers and a signal combiner.

The apparatus may comprise an R.F. operable duplexer for providing a dual transmit-receive capability to an antenna, said duplexer being for connection to an existing antenna configured for receiving, to enable said existing antenna to transmit said transmit diversity signal.

Preferably, said existing base station is a multiple air interface base station having a CDMA air interface and at least one other air interface and in which said at least one R.F. output is a low power R.F. output, said apparatus configured to extract a CDMA signal for feeding to said R.F. operable diversity unit whilst leaving signals of said at least one other air interface unchanged.

The apparatus may further comprise external amplification for the modified signals.

The apparatus may further comprise antenna control for providing such features as azimuthal beam squint and azimuthal beamwidth shaping.

Preferably, said antenna control comprises circuitry for adjusting a main lobe tilt.

According to a second aspect of the present invention there is provided a method of enhancing a base station having a CDMA air interface with receive space diversity capability so as to provide said base station with transmit diversity capability, the method comprising:
attaching a radio frequency interface unit to an R.F. output of said base station to obtain a sample of a main R.F. signal, attaching a diversity unit to said radio frequency interface unit to generate a transmit diversity signal, and connecting said diversity unit to a diversity antenna of said base station to transmit said transmit diversity signal.

Preferably, said base station comprises a passive antenna array.

Preferably, said base station comprises two transmit/receive subsystems, each for sending and receiving distinct channels.

The method may comprise adding a further passive antenna to said base station to provide a transmit diversity antenna.

The method may comprise replacing at least one existing antenna with two co-located antennas.

The co-located antennas may comprise a commonly polarized antenna arrangement or a dual polarized antenna arrangement.

Preferably, said antenna arrangement comprises at least two spaced antennas to provide receive space diversity capability, the method further comprising attaching a duplexer to a receive diversity antenna of said antenna arrangement to provide said receive diversity antenna with transmit-receive capability, thereby to transmit said transmit diversity signal therefrom.

Preferably, said R.F. output is a low power output and wherein said method further comprises adding power amplification.

The method may comprise providing said power amplification in close proximity to said antenna.

The method may comprise providing said power amplification in two modules, one for a main signal path and one for a diversity signal path.

The method may comprise providing at least one directional coupler in said radio frequency interface unit for obtaining said sample signal.

Preferably, said base station is a multiple air interface base station in which one air interface is CDMA, wherein said R.F. output is a low power output and said connecting said diversity unit comprising setting up a path from said R.F. output to extract a CDMA signal and not to extract other signals.

Preferably, said base station comprises one R.F. transmit output and two R.F. receive inputs.

The method may comprise providing antenna control for azimuthal beam squint and azimuthal beamwidth shaping.

Preferably, said antenna control comprises circuitry for adjusting a main lobe tilt.

Unless otherwise defined, all technical and scientific terms used herein have the same meaning as commonly understood by one of ordinary skill in the art to which this invention belongs. The materials, methods, and examples provided herein are illustrative only and not intended to be limiting.

Implementation of the method and system of the present invention involves performing or completing selected tasks or steps manually, automatically, or a combination thereof. Moreover, according to actual instrumentation and equipment of preferred embodiments of the method and system of the present invention, several selected steps could be implemented by hardware or by software on any operating system of any firmware or a combination thereof. For example, as hardware, selected steps of the invention could be implemented as a chip or a circuit or other hardware module. As software, selected steps of the invention could be implemented as a plurality of software instructions being executed by a computer using any suitable operating system. In any case, selected steps of the method and system of the invention could be described as being performed by a data processor, such as a computing platform for executing a plurality of instructions.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a simplified schematic diagram showing a conventional base station with receive diversity but no transmit diversity,

FIG. 2 is a simplified schematic diagram illustrating the general principle behind the present embodiments, more specifically the base station of FIG. 1 is shown in which: an RF signal is extracted and transformed into an RF diversity signal, then amplified and connected to the second antenna, to achieve transmit diversity

FIG. 3 is a simplified schematic diagram illustrating a base station arrangement having an existing space diversity antenna arrangement and a single internal MCPA per sector and no transmit diversity and employing CDMA, AMPS and CDPD transmission, and showing how the base station may be converted according to a first preferred embodiment of the present invention by addition of a low-power signal combiner, a Transmit Diversity Unit, an external MCPA, and external Duplexer to support CDMA Transmit Diversity, and receive diversity to all air interfaces.

FIG. 4 is a simplified schematic diagram illustrating a base station having an existing space diversity antenna arrangement and two MCPAs per sector and no transmit diversity and employing CDMA, AMPS and CDPD transmission, and showing a conversion involving adding a low-power signal combiner, Transmit and Diversity Unit to obtain a system arrangement according to a second preferred embodiment of the present invention supporting CDMA Transmit Diversity.

FIG. 5 is a simplified schematic diagram illustrating an existing space diversity antenna arrangement of a highly typical base station having two Duplexed Tx/Rx RF ports per sector, for two groups of CDMA carriers, and no transmit diversity, and showing how the base station may be converted by adding three Duplexers, a high-power signal combiner, Directional Coupler, Transmit Diversity Unit, and MCPA with external Duplexer, thereby to obtain a system arrangement supporting CDMA Transmit Diversity, according to a third preferred embodiment of the present invention.

FIG. 6 is a simplified schematic diagram illustrating an existing space diversity antenna arrangement of a base station having two Duplexed Tx/Rx RF ports per sector, for two groups of CDMA carriers and not having transmit diversity, and showing a conversion involving adding a Tx bandpass filter, two Directional Couplers, a Transmit Diversity Unit, an MCPA, and a separate Tx Diversity antenna to obtain a system arrangement supporting CDMA Transmit Diversity according to a fourth embodiment of the present invention.

FIG. 7 is a simplified schematic diagram illustrating a base station having an existing space diversity antenna arrangement and two Duplexed Tx/Rx RF ports per sector (for two groups of CDMA carriers) and no transmit diversity, and showing a conversion involving adding a Tx low-power combiner, a receive signal 2:1 splitter, Transmit Diversity Unit, MCPA, Duplexer, and Optional Tower-top LNA to obtain a system arrangement supporting CDMA Transmit Diversity according to a fifth preferred embodiment of the present invention.

FIG. 8 is a simplified schematic diagram illustrating two two-column antennas deployed in a base station having a space diversity antenna arrangement, and two Duplexed Tx/Rx RF ports per sector, for two groups of CDMA carriers, and not having transmit diversity, and showing a conversion comprising adding two Tx directional couplers and two Tx bandpass filters, two Transmit Diversity Units, and two MCPAs to obtain a system arrangement supporting CDMA Transmit Diversity according to a sixth preferred embodiment of the present invention.

FIG. 9 is a simplified schematic diagram illustrating a base station having an existing space diversity antenna arrangement, and two Simplex Tx and two Simplex Rx RF ports per sector, for two groups of CDMA carriers, and no transmit diversity, and showing a conversion involving adding a Tx high-power 2:1 combiner, Directional Coupler, Transmit Diversity Unit, High Power Amplifier, and two Duplexers to obtain a system arrangement supporting CDMA Transmit Diversity according to a seventh preferred embodiment of the present invention.

FIG. 10 is a simplified schematic diagram illustrating two two-column antennas deployed in a space diversity arrangement of a low-power base station having Simplex Tx and Rx RF ports and no transmit diversity, and showing a conversion comprising adding a Tx Directional Coupler, Transmit Diversity Unit, MCPA and LPA, two Duplexers, and two High-Power Phase Shifters to obtain a system arrangement supporting CDMA Transmit Diversity, Azimuthal Beam Squint and Azimuthal Beamwidth Shaping according to an eighth preferred embodiment of the present invention.

FIG. 11 is a simplified schematic diagram illustrating an existing polarization diversity antenna arrangement of a base station having Simplex Tx and Rx RF ports and no transmit diversity, and showing a conversion comprising adding a Tx Coupler, Transmit Diversity Unit, Remote Unit incorporating two Duplexers, two LNAs, one Tx Power Amplifier, and control system for Remote Electronic Tilt to obtain a system arrangement supporting CDMA Transmit Diversity according to a ninth preferred embodiment of the present invention.

FIG. 12 is a simplified schematic diagram illustrating an existing space diversity antenna arrangement of a base station having one Tx-only lower-power port, one Duplexed Tx/Rx RF port and one Simplex Rx RF port per sector and no transmit diversity and showing a conversion comprising adding a Transmit Diversity Unit, MCPA, and Duplexer to obtain a system arrangement supporting CDMA Transmit Diversity according to a tenth preferred embodiment of the present invention.

FIG. 13 is a simplified schematic diagram illustrating an existing space diversity antenna arrangement of a base station having two Duplexed Tx/Rx RF ports per sector, for two groups of CDMA carriers, and no transmit diversity and showing a conversion comprising adding two Duplexers, two Directional Couplers, a 2:1 low-power Tx signal combiner, a Transmit Diversity Unit, a separate Tx Diversity antenna, and a Remote Unit incorporating two Duplexers, two LNAs, and one Tx Power Amplifier to obtain a system arrangement supporting CDMA Transmit Diversity according to an eleventh preferred embodiment of the present invention.

FIG. 14 is a simplified schematic diagram illustrating an existing space diversity antenna arrangement of a base station having one Duplexed Tx/Rx RF port and one Simplex Rx RF port per sector and no transmit diversity, and showing a conversion comprising adding a Tx Coupler, Transmit Diversity Unit, a Remote Unit incorporating two Duplexers, two LNAs, and one Tx Power Amplifier to obtain a system arrangement supporting CDMA Transmit Diversity according to a twelfth preferred embodiment of the present invention.

FIG. 15 is a simplified schematic diagram illustrating an existing space diversity antenna arrangement of a base station having one Duplexed Tx/Rx RF port and one Simplex Rx RF port per sector and no transmit diversity and showing a conversion comprising the addition of a Tx Coupler, Transmit Diversity Unit, variable-gain Tx and Rx signal amplifiers, Duplexer, and a Remote Unit incorporating two Duplexers, two LNAs, and two Tx Power Amplifiers to obtain a system arrangement supporting CDMA Transmit Diversity according to a thirteenth preferred embodiment of the present invention.

FIG. 16 is a simplified schematic diagram illustrating an existing space diversity antenna arrangement of a low-power base station having one Duplexed Tx/Rx RF port and one Simplex Rx RF port per sector and no transmit diversity, and showing a conversion comprising adding a Tx Coupler, Transmit Diversity Unit, variable-gain Tx and Rx signal amplifiers, Duplexer, and Two Remote Units wherein each remote unit incorporates one Duplexer, one LNA, and one Tx Power Amplifier to obtain a system arrangement supporting CDMA Transmit Diversity according to a fourteenth preferred embodiment of the present invention.

FIG. 17 is a simplified schematic diagram illustrating an existing space diversity antenna arrangement of a base station having one Duplexed Tx/Rx RF port and one Simplex Rx RF port per sector and no transmit diversity and showing a conversion comprising adding a Directional Coupler, RF Dummy Load, a Duplexer, a 1:2 Splitter, a Transmit Diversity Unit, variable-gain Tx and Rx signal amplifiers, and two Remote Units each incorporating a further Duplexer, one LNA, and one Tx Power Amplifier, to obtain a system arrangement supporting CDMA Transmit Diversity according to a fifteenth preferred embodiment of the present invention.

FIG. 18 is a simplified schematic diagram illustrating an existing space diversity antenna arrangement of a base station having two Duplexed Tx/Rx RF ports per sector, for two groups of CDMA carriers, and no transmit diversity and showing a conversion comprising addition of two Tx bandpass filters, two Directional Couplers, a Transmit Diversity Unit, an MCPA, and changing one single column, antenna into a two-column antenna, leaving the other antenna as is, according to a sixteenth preferred embodiment of the present invention.

FIG. 19 is a variation of the embodiment of FIG. 17 in which the two-column antenna introduced in FIG. 18 is replaced by an X-pole antenna

### DESCRIPTION OF THE PREFERRED EMBODIMENTS

The present embodiments show a method, apparatus and system for converting a base station with a passive antenna array to support transmit diversity by applying a diversity operator to the already modulated R.F. signal. Thus the entire conversion can be carried out simply by adding components outside the base station structure at points which are easy to access. In the following a general description of the concept is followed by a series of conversion configurations for different kinds of base station. It is to be appreciated that the configurations described are not intended to be exhaustive and that the principle can be applied to other kinds of base station in ways that will be clear to the skilled person and furthermore the same principle can be applied in different ways to the kinds of base station described herein.

The principles and operation of a base station conversion kit and conversion method, and the operation of the converted base station according to the present invention may be better understood with reference to the drawings and accompanying descriptions.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

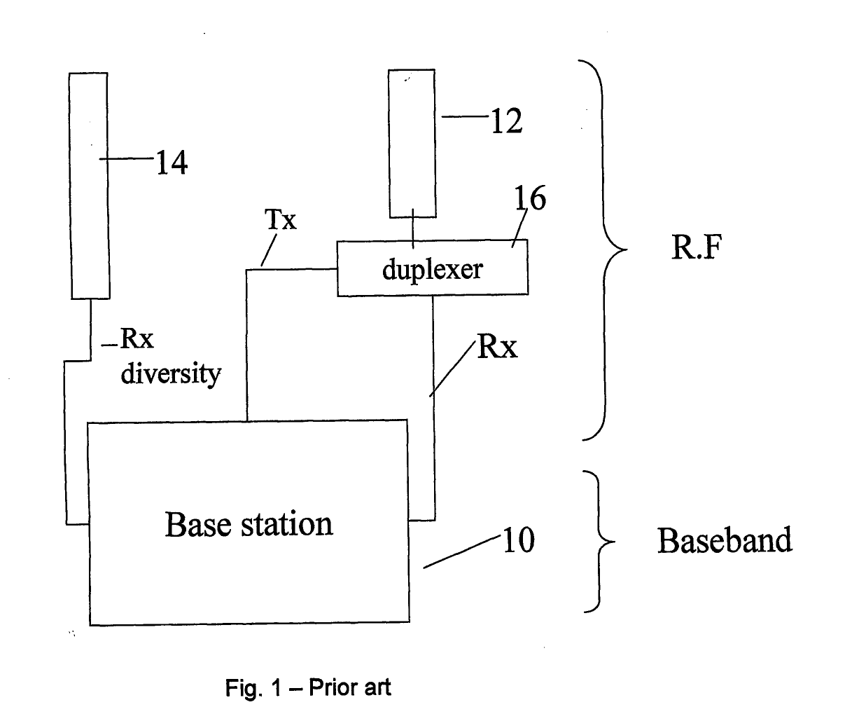

Referring now to the drawings, FIG. 1 is a simplified block diagram illustrating features of a standard base station requiring upgrading and for which upgrading according to the present invention would be beneficial. FIG. 1 illustrates transmit and receive apparatus for a single sector and in a typical base station the antennas and duplexers are repeated for each additional sector. A base station unit 10 modulates a transmission signal Tr for forward transmission via a first antenna 12. The base station receives signals from surrounding mobile units via first antenna 12 and a second, diversity, antenna 14. The received signals are labeled Rx for the first antenna 12 and Rdiv for the diversity antenna 14. As the first antenna 12 is used both for transmitting and receiving, it is supplied with duplexer 16. The second antenna 14 is used for receiving only and therefore is not equipped with a duplexer. The base station uses a passive antenna array.

An upgrade of the base station of FIG. 1 according to prior art methods involves entering the base station unit 10 to split the baseband Tx signal into two signals. A transform or delay is applied to one of the two signals to form a transmit diversity signal which then has to modulated. The conversion thus comprises fitting a transform or delay component and possibly an additional modulator if the existing modulator cannot take an extra signal. The modulated transmit diversity signal is then passed through a duplexer and taken to the diversity antenna 14. The receive diversity signal must also be routed via the new duplexer.

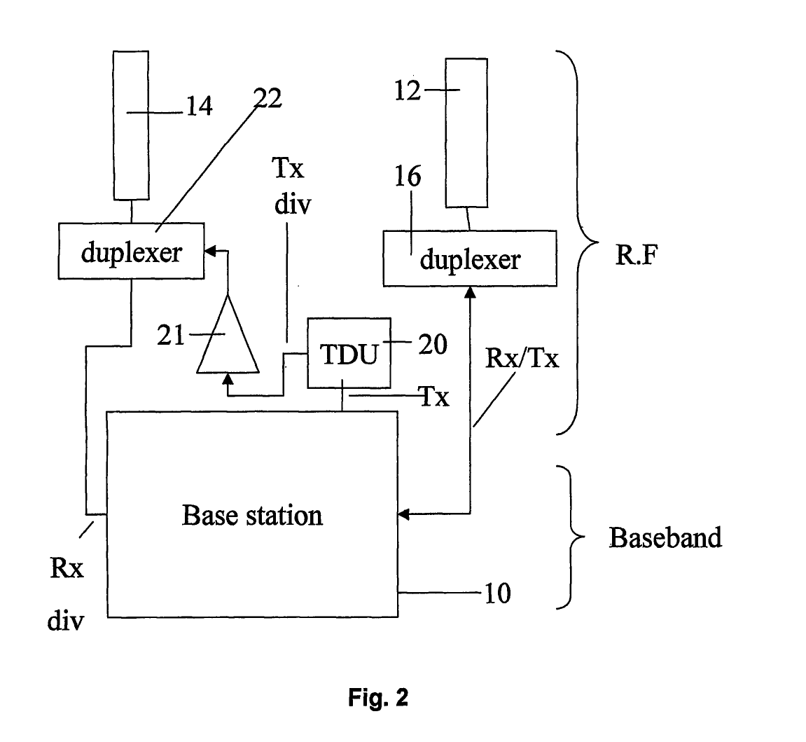

Reference is now made to FIG. 2, which illustrates the base station of FIG. 1 following upgrading according to a generalized embodiment of the present invention. Parts that are the same as in previous figures are given the same reference numerals and are not described again except to the extent necessary for an understanding of the present figure. In accordance with the generalized embodiment, an existing and operational base station serving a given cell or sector has a main antenna 12 and a diversity antenna 14. The existing antennas 12 and 14 typically continue to be employed after the augmentation process, however a transmit diversity signal path is installed from the base station to the diversity antenna 14 during the augmentation process, to provide the desired enhanced capabilities and/or enhanced performance. More specifically the modulated Tx signal as output from the RF output of the base station is split into two, and one of the two signals is supplied to a transmit diversity unit (TDU) 20 where a transform or delay or like operation is applied. The TDU typically probes the transmitted signal, and provides amplification and other signal processing as necessary.

The TDU 20 is configured to operate at RF frequencies. The signal is then amplified by power amplifier (MCPA) 21. The result is a transmit diversity signal Txdiv. At the same time, the diversity antenna 14 is supplied with its own duplexer 22 to allow it to function for both transmit and receive. The transmit diversity signal is supplied to duplexer 22 and from there to the diversity antenna 14 as a transmit signal. The receive diversity signal is diverted via the duplexer 22 and then supplied as before to the receive diversity input of the base station unit 10.

The modification shown in FIG. 2 thus adds a transmit diversity capability to existing cellular base stations while minimizing the scope and complexity of base station modifications. Likewise modifications according to the present embodiments reduce the quantity and complexity of additional subsystems needed to provide that transmit diversity capability.

As will be explained in greater detail below, in one group of embodiments, the modification may be effected using one or more integrated units including a unit intended for fixing in physical proximity to the antenna. The remote unit is typically tower-mounted and may be configured to operate with a conventional passive column array antenna or multiple such antennas. In a second group of embodiments, it is possible to extend the capability of a base station to provide transmit diversity by employing roof-mounted or ground-mounted integrated units along with a tower-mounted conventional passive antenna or multiple such antennas. The remote or ground units comprise the parts necessary to perform the modification and simply need to be connected between the RF output of the base station unit 10 and the existing antennas, as will be discussed in greater detail below.

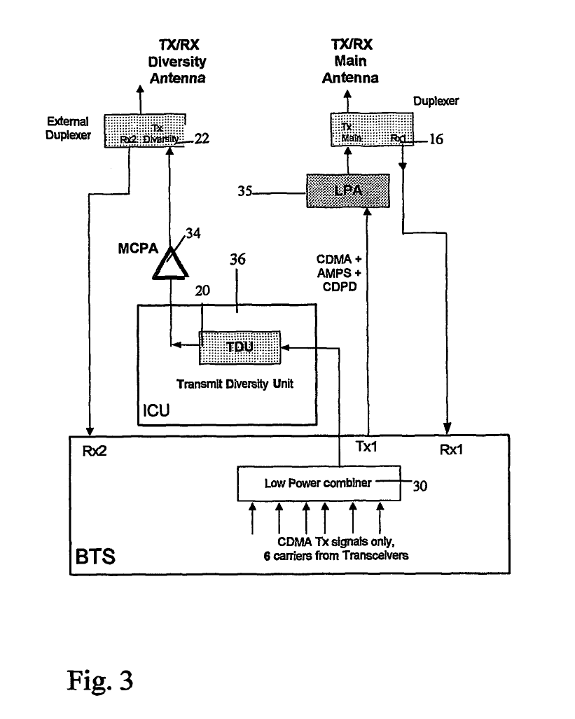

Reference is now made to FIG. 3, which is a simplified schematic diagram illustrating a typical base station having an existing receive space diversity antenna arrangement. The base station has one MCPA per sector and no transmit diversity and is a multiple air interface base station able to employ CDMA, AMPS and CDPD transmission. The base station is shown with a conversion according to a first preferred embodiment of the present invention, which involves adding a low-power signal combiner 30, a Transmit Diversity Unit 20, an external MCPA 34, and an external Duplexer 22. With the modification the base station is able to support CDMA Transmit Diversity.

The antenna arrangement initially comprises main antenna 12 and diversity antenna 14. In the figure, the antennas themselves are not shown. Augmentation of the base station in FIG. 3 converts an existing base station with receive diversity only into an augmented base station having receive diversity and transmit diversity, where the diversity may take the form of space diversity, with two spaced antennas, or polarization diversity with one dual polarized antenna.

Initially, as for FIG. 1, the existing main antenna 12 permits both transmission and reception. A single cable extends from the main antenna, located at the top of a building and connects to a Main Duplexer 16 which is located in the base station 10. The Main Duplexer serves as a coupler that allows the simultaneous transmission and reception of two signals using the same Main antenna, as explained above. To transmit a signal from the base station to a mobile unit along the forward link, the base station transceiver system sends a transmit signal comprised of either a CDMA, CDPD, or AMPS signal via a transmission cable Tx1 through a multicarrier linear power amplifier LPA 35 to a Tx Main input terminal of the Main Duplexer. The Main Duplexer then sends the transmit signal over an RF cable to the Main Antenna 12, where the transmit signal is radiated to the mobile unit. When the mobile unit transmits a signal to the base station along the reverse link, the receive signal arrives at the Main antenna 12, which then sends the receive signal to the Main Duplexer 16 via the same RF cable. The Duplexer sends the receive signal to the base station transceiver subsystem by directing the signal over the receive line Rx1.

In the embodiment of FIG. 3, the secondary Diversity antenna is a passive column array deployed in a space or polarization diversity configuration. However, the scope of the embodiment of FIG. 3 is not limited to this exemplary arrangement. Other types of secondary antenna arrangements may be employed alone or in combination.

In the initial, that is unimproved, base station antenna arrangement of FIG. 3, a single RF cable extends from the secondary Diversity antenna to the Rx diversity port of the base station. In the modification an external Diversity Duplexer 22 is connected via a first RF cable to the diversity antenna. A second cable Rx2 extends from the Diversity Duplexer to the receive input terminal of the base station transceiver subsystem. It will be appreciated that in the present embodiment, both the Main Antenna and Diversity Antenna are passive.

In order to convert the existing base station system into an augmented base station system providing transmit diversity, several further modifications are made which involve providing a Tx path to the Diversity Duplexer. Multicarrier linear amplifier MCPA 34 is connected via cable to a Tx Diversity port of the Diversity Duplexer 22. In turn the output of the Transmit Diversity Unit TDU 20 is connected to the input terminal of MCPA 34. The TDU 20 is part of Interface and Control Unit ICU 36. In turn, low-power combiner 30 drives the input terminal of the TDU 20. The various input signals connected to the low-power combiner 30 are the various single carrier CDMA transmit diversity signals to be radiated by the Diversity antenna. That is to say, the TDU, which adds the diversity feature to the diversity branch of the transmit signal, operates on the ready modulated transmit signal and not on the baseband signal. Thus the modification can be carried out using the readily available R.F. outputs of the base station unit 10 and there is no need to access the baseband signal.

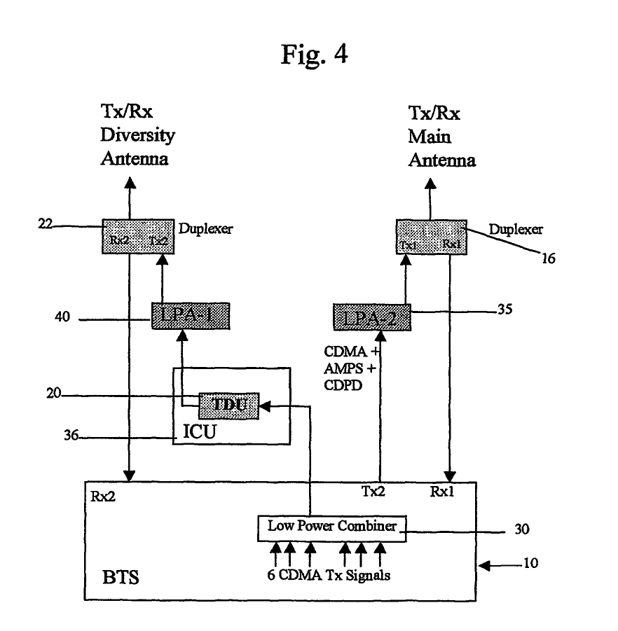

Reference is now made to FIG. 4, which is a simplified schematic diagram illustrating an existing space diversity antenna arrangement of a base station having two MCPAs per sector and no transmit diversity and employing CDMA, AMPS and CDPD transmission. The figure illustrates a conversion involving adding low-power signal combiner 30, a Transmit Diversity Unit 20 and further by arranging the connections to provide a transmit diversity signal path, thereby to obtain a system arrangement according to a second preferred embodiment of the present invention, again to support CDMA Transmit Diversity.

The conversion of the second preferred embodiment modifies an existing base station system configuration but does not change the passive antenna arrangement. The antenna arrangement comprises a main antenna 12 and a diversity antenna 14 as for FIG. 1. Augmentation of the base station in FIG. 4 converts an existing base station without transit diversity to an augmented base station having receive space diversity and transmit space diversity, in accordance with the general principle outlined in FIG. 2.

More particularly, in the initial configuration, the existing base station arrangement includes main antenna 12 that permits transmission and reception as per FIG. 1. A single cable extends from the main antenna, located at the top of a building and connects to Main Duplexer 16, typically located in the base station 10. The Main Duplexer 16 serves as a coupler that allows the simultaneous transmission and reception of two signals using the same Main antenna. To transmit a signal from the base station to a mobile unit along the forward link, the base station transceiver system sends a transmit signal comprised of either a CDMA, CDPD, or AMPS signal via a transmission cable Tx1 through a multicarrier linear power amplifier LPA-2, 35, to a Tx Main input terminal of the Main Duplexer 16. The Main Duplexer 16 then sends the transmit signal over an RF cable to the Main Antenna 12, where the transmit signal is radiated to the mobile unit.

The conversion comprises providing an alternative, diversity, route, in the base station arrangement, for transmission from the base station 10 to mobile units. A diversity path is created to send a second, diversity, set of transmission signals, as modified by TDU 20 via multicarrier linear amplifier LPA-1 40 to the Diversity antenna 14, in a similar way as was accomplished via LPA-2 35 and the Main antenna 12. In certain embodiments the path itself may already exist and the external duplexer 22, and LPA-2 35 may already be present, in which case it is only necessary to add the TDU 20.

When the mobile unit transmits a signal to the base station along the reverse link, the receive signal arrives at the Main antenna, from where it is passed to the Main Duplexer 16 via an RF cable. The Duplexer 16 sends the receive signal to the base station transceiver subsystem by directing the signal over the receive line Rx1. The receive diversity signal is simultaneously received at the diversity antenna and supplied via duplexer 22 to the transceiver subsystem.

In the embodiment of FIG. 4, the secondary Diversity antenna is a passive column array deployed in a space diversity configuration. However, the scope of the embodiment of FIG. 4 is not limited to this exemplary arrangement. Other types of secondary antenna arrangements may be employed alone or in combination, such as a polarization diversity antenna arrangement.

Within the existing base station antenna arrangement of FIG. 4, a single RF cable extends from the secondary Diversity antenna to the Diversity Duplexer 35 when added Another cable Rx2 extends from the Diversity Duplexer 35 to the receive diversity input terminal of the base station transceiver subsystem. If the diversity duplexer 35 is not present, i.e. prior to the modification, then a single Rx cable connects the diversity antenna to the receive diversity input terminal of the base station transceiver subsystem.

Both the Main Antenna and Diversity Antenna are passive.

In the modification itself, the existing multicarrier linear amplifier LPA-1, 40, which was connected via a cable to the Tx Diversity port of the Diversity Duplexer remains in place. The interface and control unit 36 is introduced into the system, and the output of the Transmit Diversity Unit TDU 20 of the Interface and Control Unit ICU 36 is now connected to the input terminal of LPA-1 40. In turn, low-power combiner 30, also added to the system, is connected to provide an additional version of the base station RF output to drive the input terminal of the TDU. Previously the only signal that had been available was the plain unsplit Tx signal. The various input signals connected to the low-power combiner 30 comprise the various single carrier CDMA transmit diversity signals to be radiated by the Diversity antenna, as for the previous embodiment, and thus the second embodiment also operates by splitting the RF transmit signal and applying a delay, transform or the like to provide an RF diversity signal.

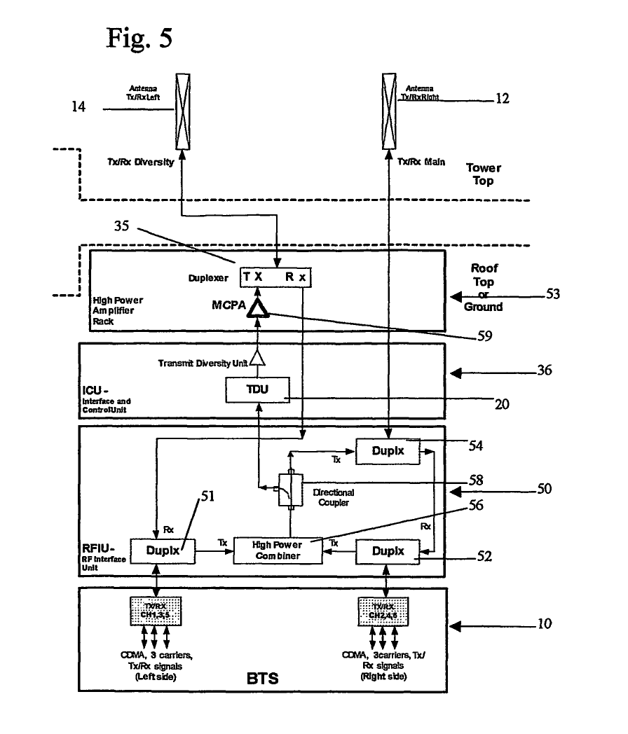

Reference is now made to FIG. 5, which is a simplified schematic diagram illustrating a highly typical base station having two Duplexed Tx/Rx RF ports per sector, for two groups of CDMA carriers and an existing space diversity antenna arrangement and lacking transmit diversity. The unmodified base station-antenna arrangement comprises base station unit 10, and antennas 12 and 14. During modification, RF interface unit RFIU 50, ICU 36, and high power amplifier rack 53 are added. The RF interface unit RFIU 50 preferably comprises three Duplexers 51, 52 and 54, a high-power signal combiner 56, and a Directional Coupler 58. ICU 36 comprises Transmit Diversity Unit 20, and the high power amplifier rack is preferably fitted with MCPA 59 and an external Duplexer 35. The result is a system arrangement supporting CDMA Transmit Diversity, according to a third preferred embodiment of the present invention.

The third preferred embodiment modifies the existing base station system configuration but does not change the passive antenna arrangement. The antenna arrangement comprises a main antenna 12 and diversity antenna 14 as previously. Only the main antenna 12 initially permits transmission and reception as explained with respect to FIG. 1.

Within the unmodified base station antenna arrangement of FIG. 5, a single RF cable extends from the secondary Diversity antenna 14 to the Diversity port of the BTS 10. The diversity port provides reception of the Diversity Receive signals, and incidentally, also provides transmission of signals on Tx Channels 1, 3 and 5. A single cable extends from the Main antenna 12, typically located at the top of a building, and also connects to the base station unit BTS 10.

Both the Main Antenna and Diversity Antenna are passive.

In order to convert the existing base station system to an augmented base station system providing transmit diversity, several modifications are made to the RF path to the Diversity Antenna 14. Diversity Duplexer 35, located in the High Power Amplifier Rack of the unmodified base station, is connected to the Diversity Antenna 14. In the modification, a multicarrier linear amplifier MCPA 59 is added to the high power amplifier rack, prior to duplexer 35, and is connected via cable to the Tx Diversity port of the Diversity Duplexer 35. The output of the Transmit Diversity Unit TDU 20 of the Interface and Control Unit ICU 36 is connected to the input terminal of the MCPA 59. In turn, the sample port of Directional Coupler 58, which is placed inside the RF Interface Unit RFIU, drives the TDU 20.

The main signal driving the Directional Coupler of the RFIU 50 is derived by first combining the various transmit signals coming from the two respective Tx ports of the base station BTS 10, one of which is connected to duplexer 51 and the other of which is connected to duplexer 52. Signal combining is performed via the two respective Duplexers 51 and 52 and High Power Combiner 56, all of which are preferably located in the RFIU 50.

Operation of the modified base station arrangement is now described. In the modified version, transmission of a signal from the base station 10 to a mobile unit along the forward link comprises the following. The existing base station transceiver system sends a transmit signal comprising a CDMA signal along channels 2, 4, or 6, via the Main Tx/Rx port of the base station BTS 10 to a Duplexer 52 located in the RF Interface Unit RFIU 50 and from there to High Power Combiner 56 in the RFIU. From the high power combiner 56, the signal is directed through Directional Coupler 58 to Main Duplexer 54 located as described in the RFIU 50. The Main Duplexer 54 then sends the transmit signal over an RF cable to the Main Antenna, where the transmit signal is radiated to the mobile unit. A diversity signal is created in TDU 36 using a signal taken from the sample output of the directional coupler 58. The diversity signal is then sent via the MCPA 59 and duplexer 35 to the diversity antenna 14.

When the mobile unit transmits a signal to the base station along the reverse link, the receive signal arrives at the Main antenna 12, which then sends the receive signal to the Main Duplexer 54 via an RF cable. The Duplexer 54 sends the receive signal to the base station transceiver subsystem by directing the signal through another Duplexer 52 in the RFIU 50 to the Main RF port of the BTS 10. A diversity receive signal may also be received at diversity antenna 14, and a single RF cable extends from the secondary Diversity antenna 14 to the Diversity Duplexer 35 located in the High Power Amplifier Rack. Another cable extends from the Diversity Duplexer to Duplexer 51 in the RFIU 50. Duplexer 51 is connected to the Diversity RF port of the BTS 10.

In the embodiment of FIG. 5, the secondary Diversity antenna 14 is a passive column array deployed in a space diversity configuration. However, the scope of the embodiment of FIG. 5 is not limited to this exemplary arrangement. Other types of secondary antenna arrangements may be employed alone or in combination, such as a polarization diversity antenna arrangement.

The architecture of the embodiment of FIG. 5 is compatible with any base station architecture, since the modification can be carried out without any need to access the low-power RF connection point typically available only with difficulty from inside the existing base station. Thus the modification can be carried out with reduced cost and complexity.

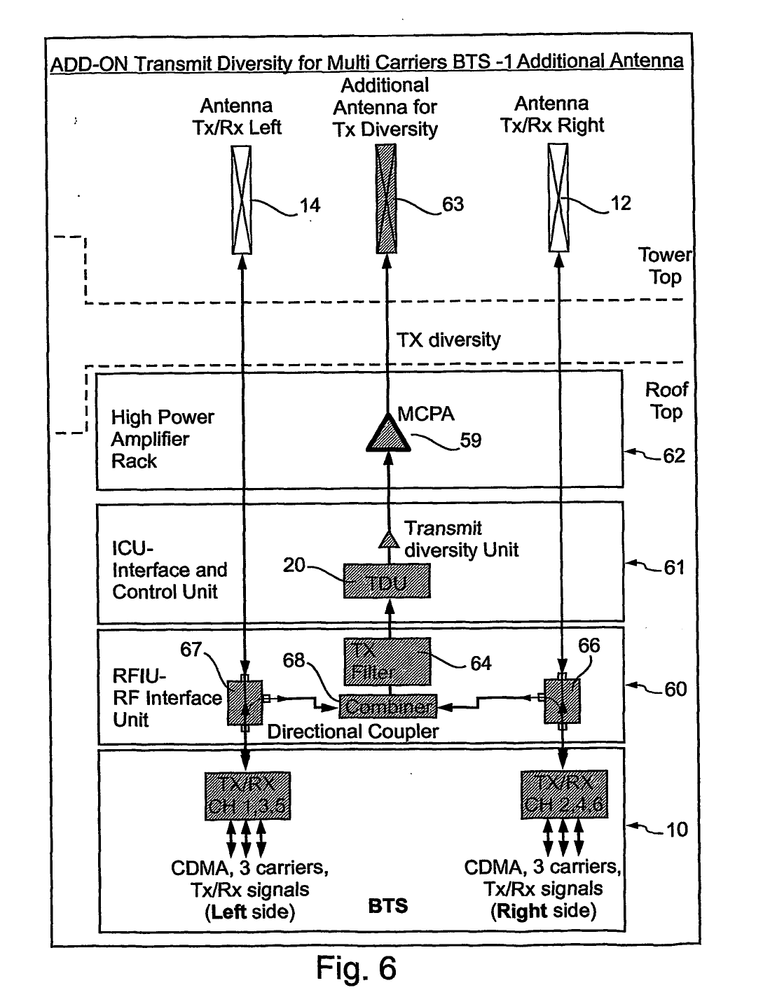

Reference is now made to FIG. 6, which is a simplified schematic diagram illustrating a fourth preferred embodiment of the present invention in which an existing space diversity antenna arrangement of the same kind as discussed with respect to FIG. 5, is converted by adding an RFIU 60, an ICU 61, a high power amplifier rack 62 and a third antenna 63. The RFIU 60 preferably comprises a Tx bandpass filters 64, two Directional Couplers 66 and 67, and a combiner 68. The ICU 61 comprises a Transmit Diversity Unit 20, and the high power amplifier rack 53 comprises MCPA 59 but this time without duplexer 35. As will be explained below, the MCPA 59 is connected to the third antenna 63 which serves as a transmit diversity antenna. The modified base station thus provides a system arrangement supporting CDMA Transmit Diversity.

The existing or unmodified base station configuration for FIG. 6 is identical to that of FIG. 5. The modification comprises connecting multicarrier linear amplifier MCPA 59 via cable to the Tx Diversity antenna 63. The output of the Transmit Diversity Unit TDU 20 of the Interface and Control Unit ICU 36 is connected to the input terminal of the MCPA. In turn, the sample output port of the low-level combiner 68 in the RFIU 60 drives the TDU 20 which produces the diversity signal.

The signal emitted from the low-level combiner in the RFIU is bandpass filtered as a result of being fed through filter 64. The Directional Couplers, which feed the combiner, are fed in turn by the two RF ports of the BTS referred to as the Main and Diversity ports.

Use of the modified base station arrangement is now described. To transmit a signal from the base station to a mobile unit along the forward link, the base station transceiver system sends a transmit signal comprising a CDMA signal (e.g., Channels 2, 4, or 6) via the Main Tx/Rx port of the base station BTS 10 to a Directional Coupler 66 in the RFIU, then over an RF cable to the Main Antenna 12, where the transmit signal is radiated to the mobile unit. The transmit signals of carriers 1,3,5 are similarly directed via the main Tx/Rx port to a directional coupler 67 in the RFIU, then over an RF cable to the main antenna 14. A diversity signal is derived by passing the sample output of the directional coupler via the combiner and bandpass filter and then to the TDU 20. From there the signal is directed to the MCPA and from there to the third antenna.

When the mobile unit transmits a signal to the base station along the reverse link, two space diversified versions of the receive signal arrive at the two Main antennas, which are then sent to the Main and diversity RF ports respectively of the BTS.

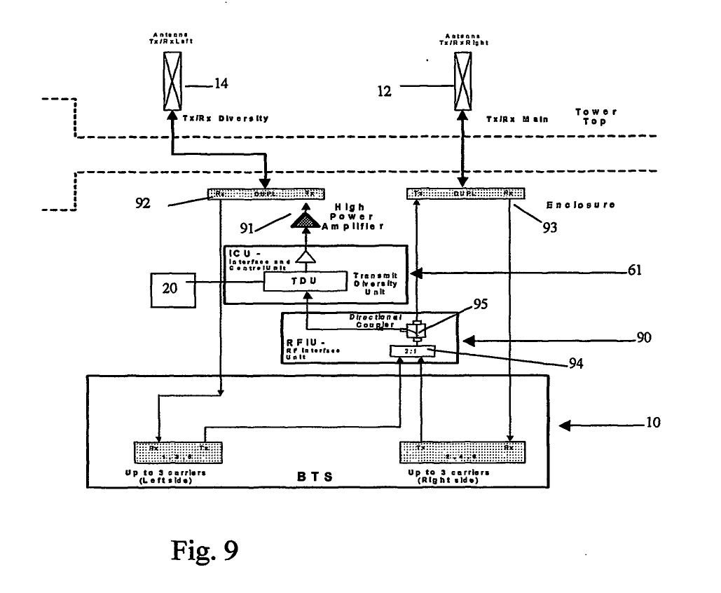

In the embodiment of FIG. 6, the Tx Diversity antenna is a passive antenna deployed in a space diversity configuration. However, the scope of the embodiment of FIG. 6 is not limited to this exemplary arrangement. Other types of secondary antenna arrangements may be employed alone or in combination, such as a polarization diversity antenna arrangement as for example discussed in FIG. 9.

The present embodiment uses three antennas per sector, which can give rise to planning difficulties. Advantages include the absence of any need for external duplexers to be provided with the modification since the first and second antennas continue to operate as before and the newly provided third antenna operates for transmit diversity only. Duplexers are associated with a certain duplexer loss and thus the lack of a duplexer leads to greater output power.

An embodiment that corresponds to the embodiment of FIG. 6 is included in U.S. Patent Application 60/330,505, and the relevant section thereof is hereby incorporated by reference.

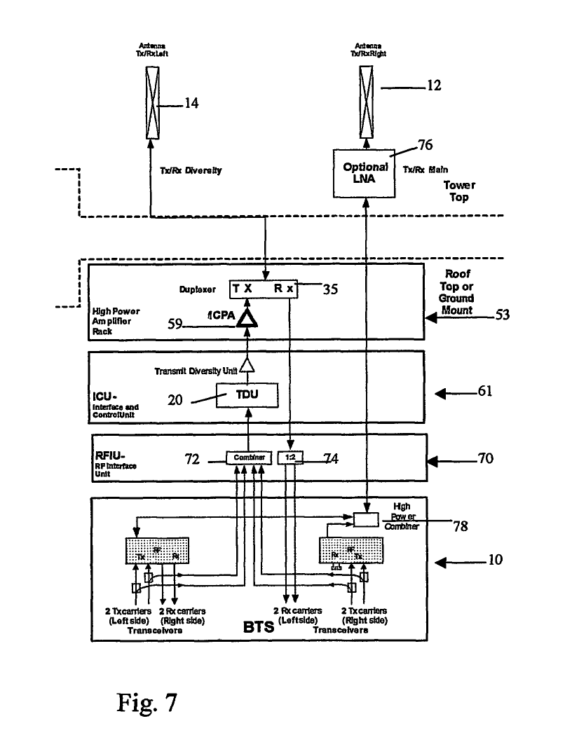

Reference is now made to FIG. 7, which is a simplified schematic diagram that illustrates an existing space diversity antenna arrangement of a base station having two Duplexed Tx/Rx RF ports per sector, so as to provide two groups of CDMA carriers. As with all the previous embodiments the unmodified base station has no transmit diversity. The figure shows a modification thereto involving adding an RFIU 70, an ICU 61, and a high power amplifier rack 53. The RFIU 70 comprises a Tx low-power combiner 72, and a receive signal 2:1 splitter 74. The ICU 36 comprises Transmit Diversity Unit 20, and the high power amplifier rack 53 comprises MCPA 59 and external Duplexer 35. In addition there is provided optional Tower-top LNA 76. The modification converts the base station to provide a system arrangement supporting CDMA Transmit Diversity according to a fifth preferred embodiment of the present invention.

As before, the conversion modifies the existing base station system configuration without changing the passive antenna arrangement. The antenna arrangement itself comprises a main antenna 12 and diversity antenna 14 as before. Augmentation of the base station according to the modification discussed in FIG. 7 converts an existing base station without transmit diversity into an augmented base station having receive space diversity and transmit space diversity, without requiring access to a baseband or low power R.F. output.

Initially, the existing base station arrangement includes a Main antenna that permits both transmission and reception. A single cable extends from the Main antenna, 14, typically located at the top of a building and connects, via a tower-mounted LNA 76, if used, to the base station BTS 10.

Within the existing base station antenna arrangement of FIG. 7, a single RF cable likewise extends from the secondary Diversity antenna 14 to the Diversity port of the BTS 10. The cable provides a means for reception of the Diversity Receive signals, as well as transmission of signals on some of the available Tx Channels.

Both the Main Antenna and Diversity Antenna are passive.

The existing base station configuration for FIG. 7 is indeed almost identical to that of FIG. 5 without the LNA 76. The differences are with regard to the augmented base station.

In order to convert the existing base station system to an augmented base station system providing transmit diversity, several modifications are made to the RF path to the Diversity Antenna. Diversity Duplexer 35, is placed in the High Power Amplifier Rack 53 and is connected to the Diversity Antenna 14. A multicarrier linear amplifier MCPA 59 is connected via cable to the Tx Diversity port of the Diversity Duplexer 35. The output of the Transmit Diversity Unit TDU 20 of the Interface and Control Unit ICU 36 is connected to the input terminal of the MCPA 59. In turn, low-power combiner 72, placed inside the RF Interface Unit RFIU 70, drives the TDU 20 to generate a diversity signal.

The signals driving the inputs of the low-power combiner 72 in the RFIU are preferably derived by sampling the various transmit signals coming from the two respective Tx ports of the RF UNIT in the base station BTS 10.

To transmit a signal from the base station to a mobile unit along the forward link, the base station transceiver system sends a transmit signal comprising a CDMA signal, via the Main Tx/Rx port of the base station BTS, to a high-power Combiner 78 located in the modified BTS. The Combiner 78 then sends the transmit signal over an RF cable to the Main Antenna, where the transmit signal is radiated to the mobile unit. The transmit diversity signal is however directed to the low power combiner 72, and from there to the TDU 20, ICPA 59, duplexer 35 and diversity antenna 14.

When the mobile unit transmits a signal to the base station along the reverse link, the receive signal arrives at the Main antenna 12, and is amplified by a tower-mounted LNA 76, which then sends the receive signal to the High Power Combiner 78 via an RF cable. It is to be noted that the Optional tower-mounted LNA 76 does not have any role in enhancing the Forward Link. The Combiner 78 sends the receive signal to the base station 10 transceiver subsystem.

Within the augmented base station system arrangement of FIG. 7, a single RF cable extends from the secondary Diversity antenna 14 to the Diversity Duplexer 35 in the High Power Amplifier Rack 53. Another cable extends from the Diversity Duplexer to Splitter 74 in the RFIU 70 which in turn is connected to the Diversity RF port of the base station 10.

In the embodiment of FIG. 7, the secondary Diversity antenna 14 is a passive column array deployed in a space diversity configuration. However, the scope of the embodiment of FIG. 7 is not limited to this exemplary arrangement. Other types of secondary antenna arrangements may be employed alone or in combination, such as a polarization diversity antenna arrangement.

Disadvantages of the embodiment of FIG. 7 are that it requires a low-power RF connection point at which RF carriers are available to which to connect the RFIU. It also requires that high-power combiner 78 be installed inside the base station.

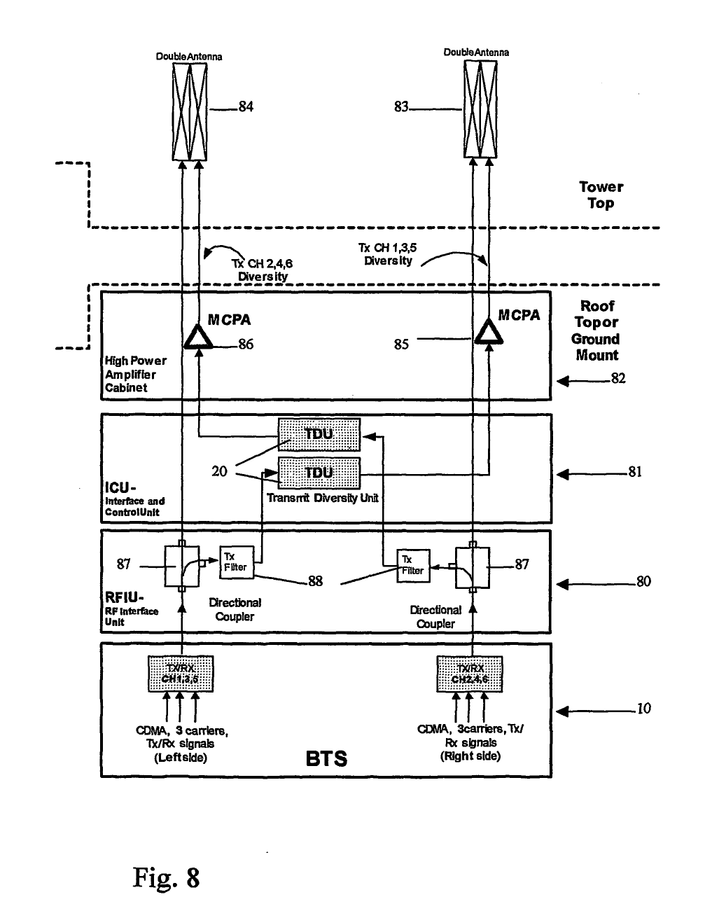

FIG. 8 is a simplified schematic diagram that illustrates a modification suitable for a base station having two Duplexed Tx/Rx RF ports per sector, for two groups of CDMA carriers. The base station has two two-column antennas deployed in a space diversity arrangement and, as with the previous unmodified base stations, does not have transmit diversity. The base station is converted by adding an RFIU 80, an ICU 81, and a high power amplifier cabinet 82. The double antennas are denoted 83 and 84. The high power amplifier rack or cabinet 82 comprises two MCPAs 85 and 86. The ICU 81 comprises two TDUs 20. RFIU 80 preferably comprises two Tx directional couplers 87 and 2 Tx bandpass filters 88. The conversion provides a system arrangement supporting CDMA Transmit Diversity according to a sixth preferred embodiment of the present invention.

The present base station may have existing single-column antennas, which are replaced by a two-column antenna having approximately the same physical size as the existing single-column antennas. Alternatively the two-column antennas are available from the unmodified base station.

The rest of the augmentation process involves providing two trait diversity paths, one to each double antenna. To this end, the two Tx directional couplers 87 and the two Tx bandpass filters 88 feed respective Tx signals to two Transmit Diversity Units 20. Two MCPAs 85 and 86 placed at the outputs of the Transmit Diversity Units 20 allow the augmented system to support CDMA Transmit Diversity by providing respective diversity signals for RF signals emitted by either port of the base station.

A primary advantage of the embodiment of FIG. 8 is that there are no external Duplexers and thus no corresponding duplexer losses, thereby increasing the available Tx power.

Reference is now made to FIG. 9, which is a simplified block diagram illustrating a base station having 2 Simplex Tx and 2 Simplex Rx R.F. ports per sector. The base station transmits and receives two groups of CDMA carriers per sector and has an existing receive space diversity antenna arrangement and no transmit diversity. The diagram illustrates a conversion involving adding an RFIU 90, an ICU 61, a high power amplifier 91 and two duplexers 92 and 93. The RFIU 90 comprises a Tx high-power 2:1 combiner 94, and Directional Coupler 95. The ICU 61 comprises Transmit Diversity Unit 20. The conversion provides a system arrangement supporting CDMA Transmit Diversity according to a seventh preferred embodiment of the present invention.

The augmentation process involves connecting and adding Tx high-power 2:1 combiner 94 to the Tx ports of base station 10 to obtain an all-carriers transmit signal. The combiner 94 feeds the all-carriers Tx signal to the Directional Coupler 95, which samples a low level signal and feeds it via the sample output to the Transmit Diversity Unit 20. High Power RF Amplifier 91 amplifies the output of the TDU 20 to supply a high-power Transmit Diversity signal via duplexer 92 to the left antenna Duplexers 92 and 93, connected to the Main and Diversity antennas respectively, isolate the high-power Tx and low-power Rx signals.

The result is that the modified base station is able to support CDMA Transmit Diversity using the existing antennas, and the modification can be completed without needing to access the baseband transmit signal.

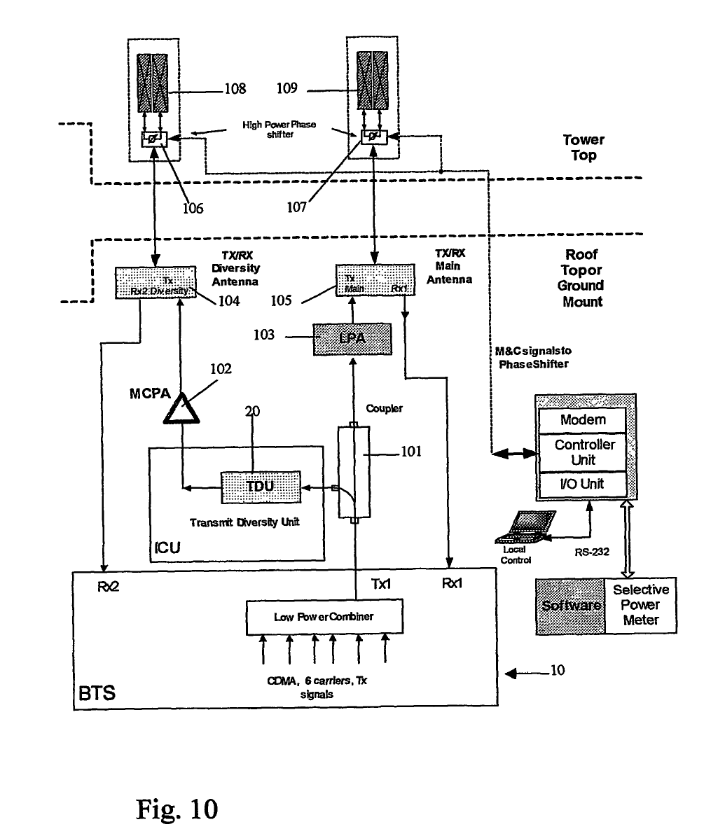

Reference is now made to FIG. 10, which is a simplified schematic diagram illustrating a base station conversion which affords two significant capabilities: Azimuthal Beam Squint and Azimuthal Beamwidth Shaping. These capabilities allow interference and Soft handoff management as well as load management among the sectors of a base station. The result is higher capacity and equipment utilization, particularly useful for cell sites with uneven sector loading.

A low-power base station has Simplex Tx and Rx RF ports and no transmit diversity. The antenna arrangement initially comprises two single column antennas deployed in a space diversity arrangement, which are preferably replaced with two two-column antennas likewise deployed. The conversion comprises adding an ICU 100, a Tx Directional Coupler 101, MCPA 102, LPA 103, two Duplexers 104 and 105, and two High-Power Phase Shifters 106 and 107, which are attached respectively to two two-column antennas 108 and 109. The ICU 100 comprises a TDU 20. The conversion provides a system arrangement supporting CDMA Transmit Diversity, Azimuthal Beam Squint and Azimuthal Beamwidth Shaping according to an eighth preferred embodiment of the present invention.

As mentioned above, the augmentation process involves replacing existing two single-column antennas with two two-column antennas, and the new antennas include high power phase shifters 106 and 107. The Phase Shifters 106 and 107 are preferably driven by a remotely located control system. The control system may be either manual or automatic, and serves to alter the antenna pattern for the two-column structure by adjusting the main lobe boresight azimuth.

The embodiment according to FIG. 10 is preferably implemented in conjunction with a low-power base station having Simplex Tx and Rx RF ports. However it is also possible to deploy the Azimuthal Beam Squint and Azimuthal Beamwidth Shaping capabilities with other base station configurations.

The modification process according to the eighth preferred embodiment also involves adding Tx Directional Coupler 101, whose sample port in turn drives the Transmit Diversity Unit (TDU) 20. The TDU 20 generates a diversity signal which in turn drives the MCPA 102. The mainline signal from the Tx Directional Coupler in turn drives the LPA 103. The two Duplexers 104 and 105, respectively connected to the Diversity and Main antennas, isolate the high-power Tx and low-power Rx signals as in previous embodiments. The result is a modification that allows the base station to support CDMA Transmit Diversity and provide Azimuthal Beam Squint and Azimuthal Beamwidth Shaping capabilities. Remote and/or autonomous control of the Beam Squint and Beam Shaping are provided by a suitable control system.

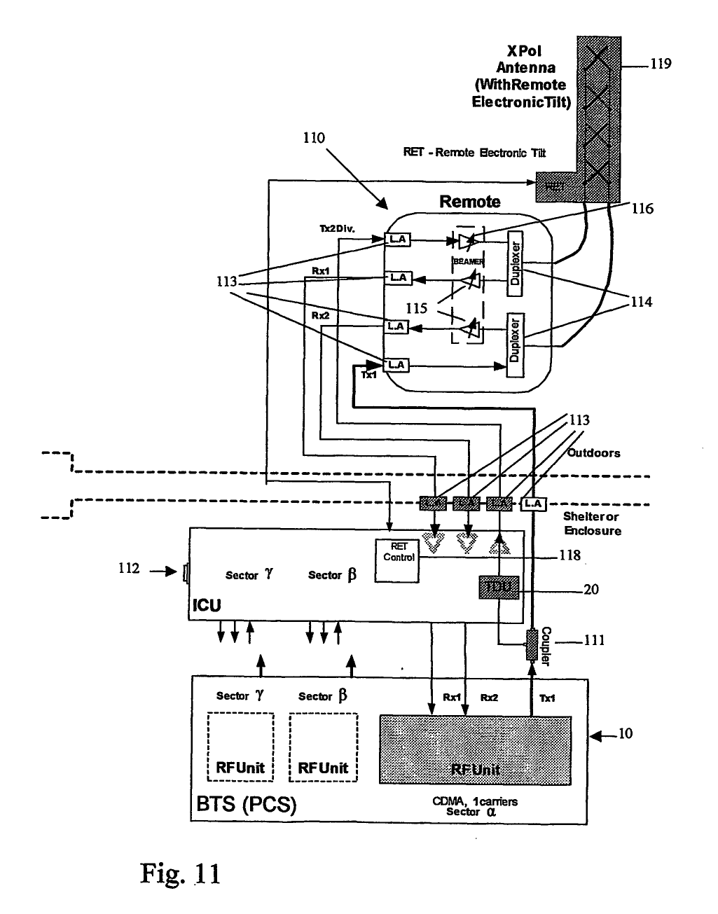

Reference is now made to FIG. 11, which is a simplified schematic diagram illustrating a base station having Simplex Tx and Rx RF ports and no transmit diversity. The base station has an existing polarization diversity antenna arrangement.

The conversion comprises adding a Remote unit 110, a Tx Coupler 111, and ICU 112.

Lightning arresters (LA) 113 may be added as required. ICU 112 comprises Transmit Diversity Unit 20. The Remote Unit 110 incorporates two Duplexers 114, two LNAs 115, and Tx Power Amplifier 116. The ICU preferably also comprises a control system for Remote Electronic Tilt (RET) 118. Antenna 119 is an X pole antenna with remote electronic tilt. The conversion provides an upgraded base station able to support CDMA Transmit Diversity according to a ninth preferred embodiment of the present invention. FIG. 11 illustrates a base station augmentation which generally affords better Tx power amplifier efficiency than other approaches. The embodiment of FIG. 11 preferably employs Remote Unit 110 which is intended to be installed in physical proximity to the antenna(s). Losses encountered in the RF cable between the Remote Unit and antenna are thereby kept to a minimum. The embodiment of FIG. 11 is particularly appropriate for urban areas with strict zoning challenges, since Transmit Diversity is achieved using only a single antenna per sector. The low loss of the Rx cables provides an enhanced SNR for the Reverse link.

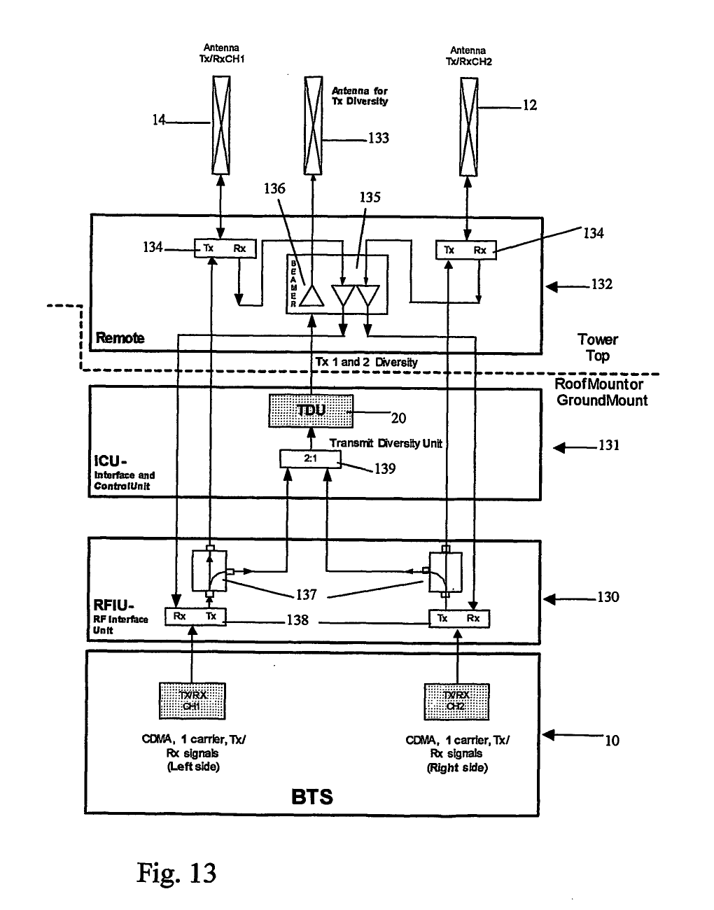

The embodiments of FIGS. 13-17 below also employ the Remote Unit as will be described herein, and the benefits of a tower-top Remote Unit as discussed in accordance with the present embodiment apply to those embodiments as well.

The embodiment of FIG. 11 is an upgrade to a base station having Simplex Tx and Simplex Rx RF ports. The augmentation process involves adding Tx Coupler 111, and the coupled or sample port feeds the Transmit Diversity Unit (TDU) 20. The TDU 20 in turn feeds a Diversity Tx signal to the Remote Unit 110. The remote unit 110 incorporates two Duplexers 114, two LNAs 115, one Tx Power Amplifier 116, and a control system for Remote Electronic Tilt to allow easier site optimization. The embodiment of FIG. 11 thus provides CDMA Transmit Diversity.

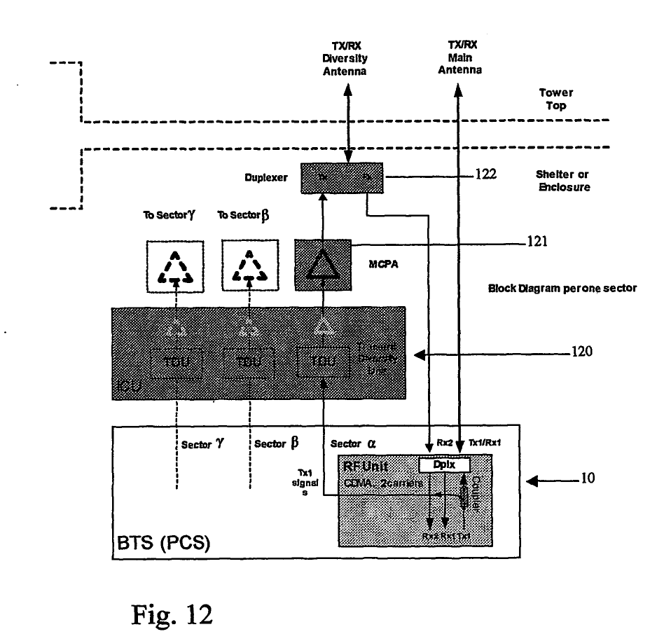

FIG. 12 is a simplified schematic diagram which illustrates a base station having one Tx-only lower-power port, one Duplexed Tx/Rx RF port and one Simplex Rx RF port per sector. The initial configuration of the base station has no transmit diversity. The antenna arrangement is a receive space diversity antenna arrangement. The figure illustrates a conversion comprising adding an ICU 120, an MCPA 121, and Duplexer 122. ICU 120 comprises a TDU 20. The conversion provides an augmented base station supporting CDMA Transmit Diversity according to a tenth preferred embodiment of the present invention.

In the augmentation of FIG. 12, only one Tx Power Amplifier per sector is added in the conversion. The embodiment requires the availability of a Tx-only lower-power port at the base station. The augmentation of FIG. 12 also employs a Duplexed Tx/Rx RF port and a Simplex Rx RF port per sector. The TDU is connected to receive a signal from the low-power TX only RF port of the base station 10. The TDU 20 in turn drives the MCPA 121 and the Duplexer 122, which is connected to the Diversity Antenna 14. The arrangement allows use of just two antennas per sector.

The embodiment of FIG. 10 requires a low-power RF connection point having the RF carriers, and is thus only applicable to certain base stations.

Reference is now made to FIG. 13, which is a simplified schematic diagram illustrating diagram illustrating a base station having two Duplexed Tx/Rx RF ports per sector, for two groups of CDMA carriers. The unmodified base station has no transmit diversity but, as with previous embodiments, the antenna arrangement has existing receive space diversity. The figure illustrates a conversion comprising adding an RFIU 130, an ICU 131 and a remote unit 132. The conversion also comprises the addition of an extra Tx diversity antenna 133. The Remote Unit 132 preferably incorporates two Duplexers 134, two LNAs 135, and one Tx Power Amplifier 136. RFIU 130 comprises two Directional Couplers 137 and two duplexers 138. ICU 131 comprises a 2:1 low-power Tx signal combiner 139 and Transmit Diversity Unit 20. The conversion provides an improved base station arrangement supporting CDMA Transmit Diversity according to an eleventh preferred embodiment of the present invention.

FIG. 13, like the previous embodiment, illustrates an augmentation of the base station in which just one additional Tx Amplifier 136 per sector is employed, resulting in minimizing of output looses. The eleventh preferred embodiment has the advantage of being a more universal augmentation solution than the previous since it requires only the standard, and generally easy to access, base station connections, as opposed to the specialized base station connections required by some of the previous embodiments. The embodiment does however require a third antenna per sector. The augmentation process involves adding two Duplexers 138 in the vicinity of the Duplex RF ports of base station unit 10. In turn, the two Directional Couplers 137 provide at their sample outputs a low-power Tx signal, which is fed to the 2:1 low-power Tx signal combiner 139, and on to the Transmit Diversity Unit 20. In the present embodiment, the separate Tx Diversity antenna is fed by the Remote Unit 132 which, as described above, incorporates two Duplexers 134, two LNAs 135, and one Tx Power Amplifier 136. The LNAs improve the system SNR and help balance the radio link after the Transmit Diversity has been able to improve the Forward Link.

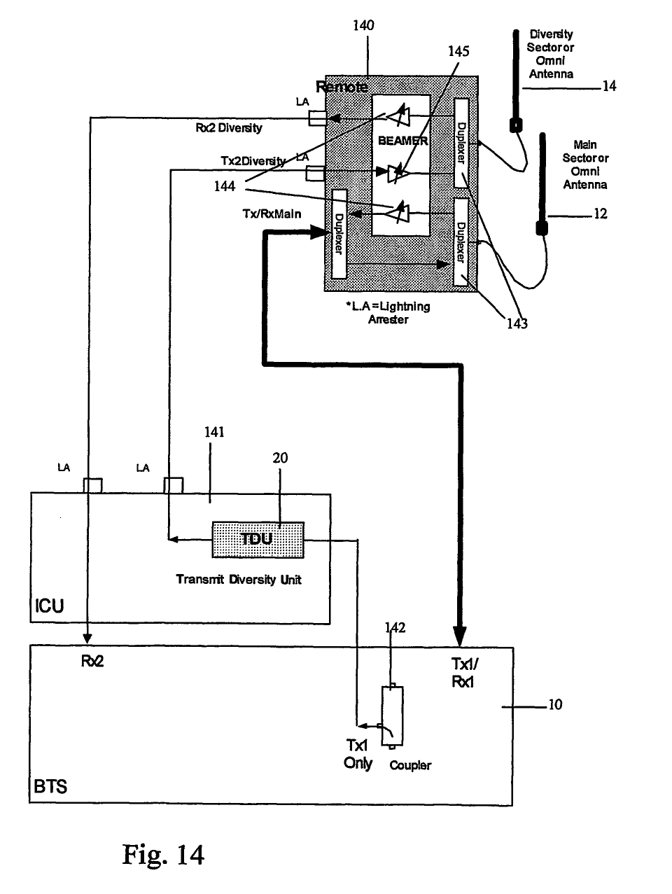

Reference is now made to FIG. 14, which is a simplified schematic diagram illustrating a base station having one Duplexed Tx/Rx RF port and one Simplex Rx RF port per sector and an existing receive space diversity antenna arrangement. The unmodified base station lacks transmit diversity, as with the previous embodiments. The figure shows a conversion comprising adding a remote unit 140 and an ICU 141. A Tx Coupler 142 is inserted within the base station unit 10. Transmit Diversity Unit 20 is located within the ICU 141, and the Remote Unit 140 comprises three Duplexers 143, two LNAs 144 and one Tx Power Amplifier 145. The modification upgrades the base station to support CDMA Transmit Diversity according to a twelfth preferred embodiment of the present invention.

The twelfth preferred embodiment employs a Remote Unit, as with certain of the previous embodiments. The twelfth preferred embodiment is appropriate for base stations in which all of the CDMA carriers are present on one RF port of the base station. The augmentation according to the twelfth preferred embodiment is carried out on the kind of base station having one Duplexed Tx/Rx RF port and one Simplex Rx RF port per sector. The augmentation process involves adding Tx Coupler 142 at a low RF power sampling point inside the base station 10. The sample output of the coupler 142 feeds the Transmit Diversity Unit 20 to generate a diversity signal which in turn feeds the Tx Power Amplifier 145 in the Remote Unit 140. As before, the Remote Unit incorporates three Duplexers 143, two LNAs 144, and the Tx Power Amplifier 145. As explained, the twelfth preferred embodiment requires a low-power RF connection point where RF carriers are available.

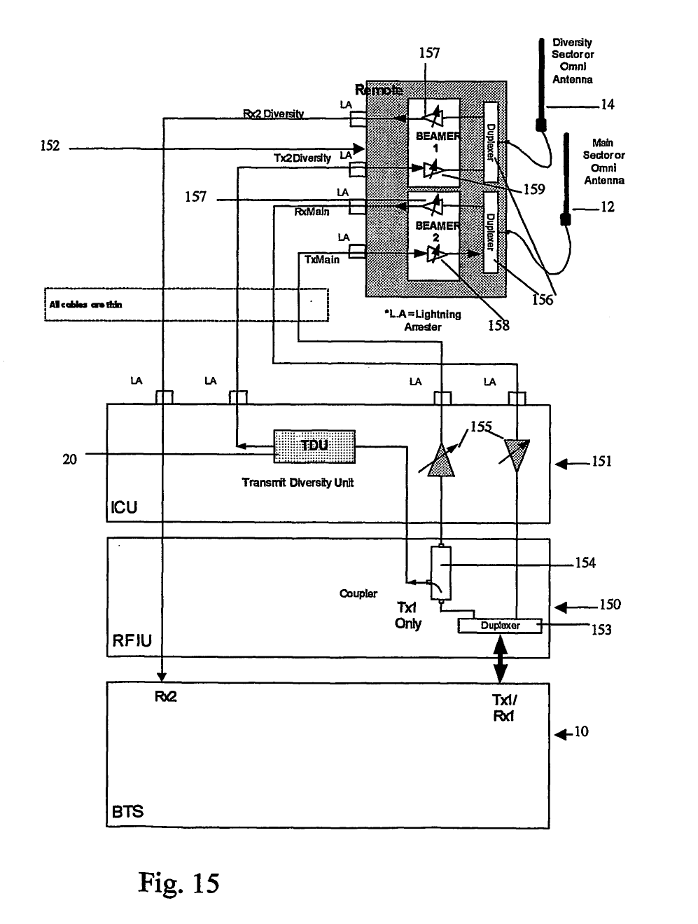

Reference is now made to FIG. 15, which is a simplified schematic diagram illustrating a base station having one Duplexed Tx/Rx RF port, one Simplex Rx RF port per sector and an existing receive space diversity antenna arrangement. As with the previous embodiments, the unmodified arrangement lacks transmit diversity. The modification comprises an RFIU 150, an ICU 151 and a remote unit 152. The RFIU 150 comprises a duplexer 153 and a Tx Coupler 154. The ICU 151 comprises Transmit Diversity Unit 20 and variable-gain Tx and Rx signal amplifiers 155. Remote Unit 152 comprises two Duplexers 156, two LNAs 157, and two Tx Power Amplifiers 158 and 159 on the transmit main and diversity paths respectively. The signal amplifiers 155 are a series of digitally controlled amplifiers that serve as preamplifiers for the power amplifier, matching between the requirements of the input to the power amplifier, and the output available from the BTS. The modification provides an upgraded base station arrangement supporting CDMA. Transmit Diversity according to a thirteenth preferred embodiment of the present invention.

Augmentation according to the thirteenth preferred embodiment provides an arrangement in which the Tx power levels for both Main and Diversity Tx paths are set, by the two power amplifiers 158 and 159, within the Remote Unit itself, and the two power amplifiers are therefore adjustable. Again the two existing column antennas retain the existing space diversity arrangement of the unmodified base station, but in the modification are used in conjunction with the Remote Unit 152.

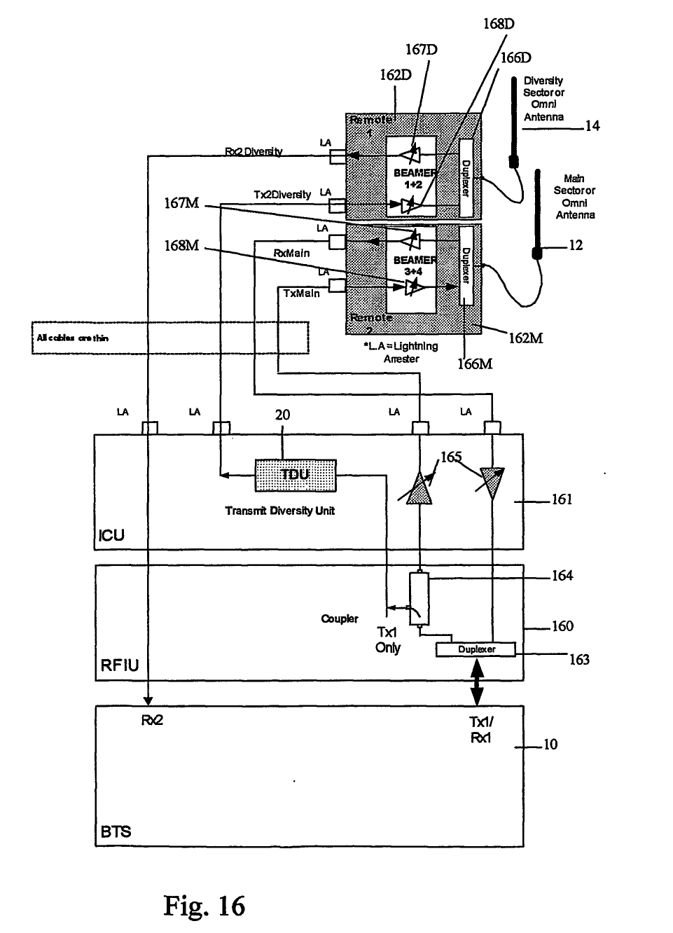

Reference is now made to FIG. 16, which is a simplified diagram illustrating a low-power base station having one Duplexed Tx/Rx RF port and one Simplex Rx RF port per sector, and an existing receive space diversity antenna arrangement. The unmodified base station lacks transmit diversity. The figure shows a conversion comprising adding an RFIU 160, an ICU 161 and two remote units, 162M for the main signal path and 162D for the diversity signal path. RFIU 160 comprises duplexer 163 and Tx Coupler 164. The sample output of the Tx coupler 164 is fed to TDU 20 of ICU 161, which generates the diversity signal. Apart from the TDU 20, the ICU 161 also comprises variable-gain Tx and Rx signal amplifiers 165. The two Remote Units 162M and 162D each incorporate a Duplexer 166M and 166D respectively, one LNA 167M and 167D respectively, and one Tx Power Amplifier 168M and 168D respectively. The modification provides the base station with CDMA Transmit Diversity capability according to a fourteenth preferred embodiment of the present invention.

Splitting of the remote unit into two halves, one for the main and one for the diversity path, facilitates maintenance and reduces sector down-time. In practice, a single Modular Remote Unit is used, which is split into two identical halves, access to each half being such as not to interfere with operation of the other.

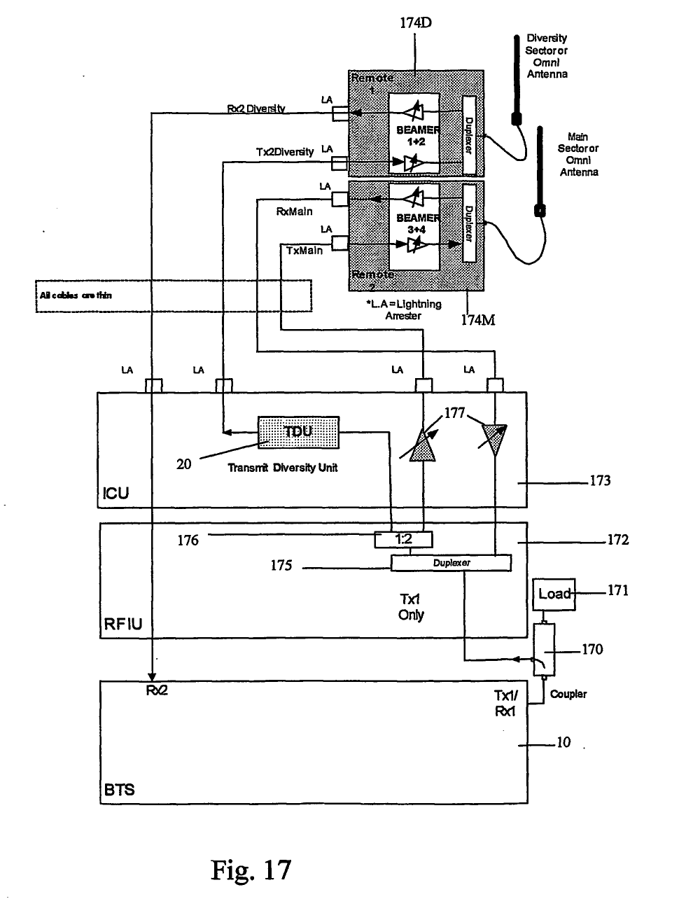

Reference is now made to FIG. 17, which is a simplified schematic diagram illustrating a base station having one Duplexed Tx/Rx RF port and one Simplex Rx RF port per sector and having an existing receive space diversity antenna arrangement. Again, the unmodified base station does not have transmit diversity. The modification illustrated in FIG. 17 comprises adding a Directional Coupler 170 with an RF dummy load 171, an RFIU 172, an ICU 173 and two remote units 174M and 174 D for the main and diversity paths respectively. RFIU 172 comprises a Duplexer 175, and 1:2 Splitter 176. The ICU 173 comprises a Transmit Diversity Unit 20 and variable-gain Tx and Rx signal amplifiers 177. The Remote Units 174M and 174D are the same as for the previous embodiment, each incorporating one Duplexer, one LNA, and one Tx Power Amplifier. The modification upgrades the base station to support CDMA Transmit Diversity according to a fifteenth preferred embodiment of the present invention.

In the upgrade according to the fifteenth embodiment, the components of the modification are designed to be quickly and easily removed from service so that the base station can be returned to its initial configuration if desired. The approach used in the fifteenth embodiment employs non-radiating RF Load 171 to dissipate the existing base station Tx power. The Coupler 170 and Duplexer 175, located at the Tx1/Rx1 RF port of base station unit 10, sample the Tx signal to drive the TDU 20. Variable-gain Tx and Rx signal amplifiers 177 help to set the appropriate base station RF interface levels.

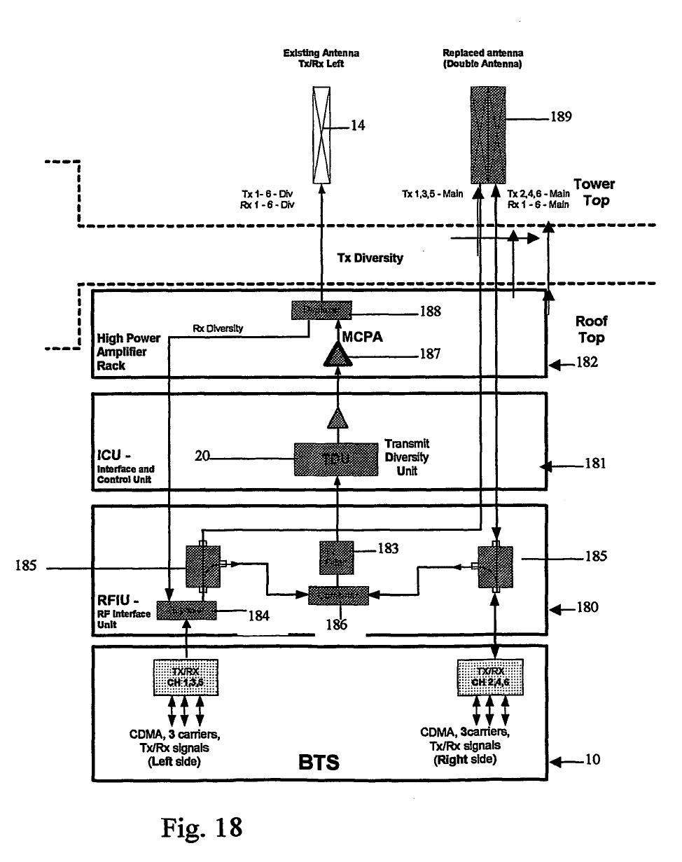

Reference is now made to FIG. 18, which is a simplified schematic diagram illustrating a base station having two Duplexed Tx/Rx RF ports per sector, for two groups of CDMA carriers and having an existing receive space diversity antenna arrangement. As before the unmodified base station lacks transmit diversity. The figure illustrates a conversion comprising the addition of an RFIU 180, an ICU 181, and a high power amplifier rack 182. The RFIU 180 includes two Tx bandpass filters 183, a duplexer 184, two Directional Couplers 185, and a combiner 186. The ICU 181 includes a Transmit Diversity Unit 20 and the high power amplifier rack includes MCPA 187 and second duplexer 188. In addition a single-column antenna is exchanged for a two-column antenna 189. The other antenna 14, is left unchanged. The modification provides a CDMA transmit diversity capability to the base station according to a sixteenth preferred embodiment of the present invention.

In the modification of FIG. 18, the new antenna 189 transmits channels 1,3,5 on one column and channels 2,4,6 on the second column. The existing antenna 14 serves for Tx and Rx diversity for all of the channels.

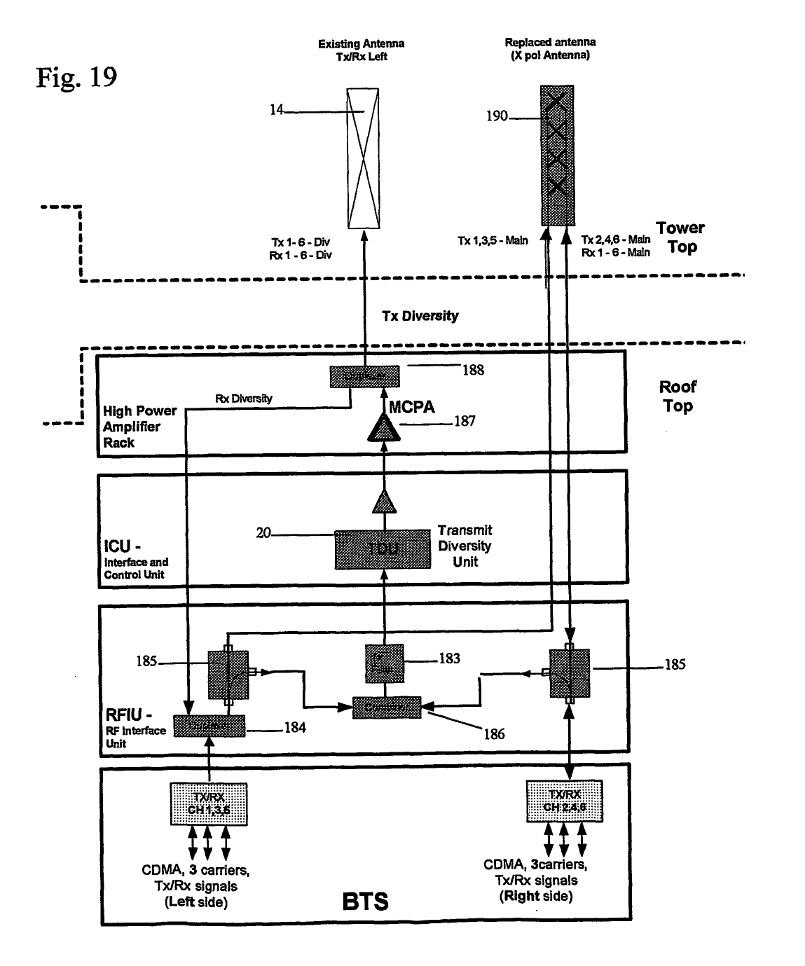

Reference is now made to FIG. 19, which is a variation of the embodiment of FIG. 18. In FIG. 19, the same modification is applied to the same kind of base station, and parts that are the same as in previous figures are given the same reference numerals and are not described again except to the extent necessary for an understanding of the present figure. The difference between FIGS. 18 and 19, is that in FIG. 19, in place of a two-column antenna 189, an X-pole antenna 190 is used.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed is:

1. Upgrading apparatus for obtaining a transmit diversity signal for transmission alongside a main R.F. signal using at least one antenna, the apparatus comprising:
an R.F. operable signal extractor for extracting a sample of said R.F. main signal, and
an R.F. operable diversity unit for transforming said R.F. sample signal thereby to form said transmit diversity signal, said apparatus being configured for insertion between at least one R.F. output of an existing cellular base station and a passive diversity antenna, said main R.F. signal being obtained from said R.F. output, thereby to confer upon said existing cellular base station a transmit diversity capability.

2. Apparatus according to claim 1, wherein said existing base station comprises a single R.F. output for transmit signals and at least two R.F. inputs for receive signals.

3. Apparatus according to claim 2, wherein said single R.F. output is a low power output, said apparatus further comprising amplification.

4. Apparatus according to claim 1, wherein said R.F. signal is a low power R.F. signal and said apparatus further comprises amplification circuitry for amplifying said main and said diversity signals.

5. Apparatus according to claim 1, wherein said R.F. signal is a high power R.F. signal.

6. Apparatus according to claim 1, wherein said base station comprises two receive/transmit subsystems, each for transmitting and receiving separate channels.

7. Apparatus according to claim 6, wherein said diversity antenna is for adding to said base station as part of said upgrading.

8. Apparatus according to claim 6, wherein said apparatus comprises two co-located antennas for substituting with said at least one antenna.

9. Apparatus according to claim 6, wherein said apparatus comprises two co-located antenna parts for substituting with said at least one antenna wherein said antenna parts form at least one of a group comprising a two-column antenna and a dual polarized antenna.

10. Apparatus according to claim 1, wherein said passive antenna comprises at least two antenna elements, thereby to provide receive space diversity capability.

11. Apparatus according to claim 1, wherein said cellular base station comprises a CDMA air interface, and wherein said main signal and said diversity signal comprise multiple CDMA carriers.

12. Apparatus according to claim 6, wherein said signal extractor is located in proximity to said R.F. output.

13. Apparatus according to claim 6, wherein said signal extractor is located within a housing configured for connection in proximity to said base station.

14. Apparatus according to claim 6, wherein said R.F. signal is a low power R.F. signal, said apparatus further comprises amplification circuitry for amplifying said main and said diversity signals, and said amplification circuitry is located in proximity to the respective antennas.

15. Apparatus according to claim 14, wherein said amplification circuitry is located within a housing unit configured for connection in proximity to said passive antenna.

16. Apparatus according to claim 15, wherein said housing unit is a modular unit comprising a first module for a main signal path and a second module for a diversity signal path.

17. Apparatus according to claim 6, wherein said cellular base station comprises a plurality of outputs and said signal extractor comprises a signal combiner, said sample comprising a combination of signals from said outputs.

18. Apparatus according to claim 6, wherein said signal extractor comprises at least one directional coupler.

19. Apparatus according to claim 6, wherein said base station comprises a plurality of R.F. outputs and said signal extractor comprises a plurality of directional couplers.

20. Apparatus according to claim 6, wherein said base station comprises a plurality of R.F. outputs, and said signal extractor comprises a plurality of directional couplers and a signal combiner.

21. Apparatus according to claim 1, further comprising an R.F. operable duplexer for providing a dual transmit-receive capability to an antenna, said duplexer being for connection to an existing antenna configured for receiving, to enable said existing antenna to transmit said transmit diversity signal.

22. Apparatus according to claim 1, wherein said existing base station is a multiple air interface base station having a CDMA air interface and at least one other air interface and in which said at least one R.F. output is a low power R.F. output, said apparatus configured to extract a CDMA signal for feeding to said R.F. operable diversity unit whilst leaving signals of said at least one other air interface unchanged.

23. Apparatus according to claim 22, further comprising amplification.

24. Apparatus according to claim 1, further comprising antenna control for providing azimuthal beam squint and azimuthal beamwidth shaping.

25. Apparatus according to claim 24, wherein said antenna control comprises circuitry for adjusting a main lobe tilt.

26. A method of enhancing a base station having a CDMA air interface with receive space diversity capability so as to provide said base station with transmit diversity capability, the method comprising:
attaching a radio frequency interface unit to an R.F. output of said base station to obtain a sample of a main R.F. signal,
attaching a diversity unit to said radio frequency interface unit to generate a transmit diversity signal, and
connecting said diversity unit to a diversity antenna of said base station to transmit said transmit diversity signal.

27. The method of claim 26, wherein said base station comprises a passive antenna array.

28. The method of claim 26, wherein said base station comprises two transmit/receive subsystems, each for sending and receiving distinct channels.

29. The method of claim 28, further comprising adding a further passive antenna to said base station to provide a transmit diversity antenna.

30. The method of claim 28, further comprising replacing at least one existing antenna with two co-located antennas.

31. The method of claim 30, wherein said co-located antennas comprise one of a group comprising a commonly polarized antenna arrangement and a dual polarized antenna arrangement.

32. The method of claim 26, wherein said antenna arrangement comprises at least two spaced antennas to provide receive space diversity capability, the method further comprising attaching a duplexer to a receive diversity antenna of said antenna arrangement to provide said receive diversity antenna with transmit-receive capability, thereby to transmit said transmit diversity signal therefrom.

33. The method of claim 26, wherein said R.F. output is a low power output and wherein said method further comprises adding power amplification.

34. The method of claim 33, further comprising providing said power amplification in close proximity to said antenna.

35. The method of claim 34, further comprising providing said power amplification in two modules, one for a main signal path and one for a diversity signal path.

36. The method of claim 26, comprising providing at least one directional coupler in said radio frequency interface unit for obtaining said sample signal.

37. The method of claim 26, wherein said base station is a multiple air interface base station in which one air interface is CDMA, wherein said R.F. output is a low power output and said connecting said diversity unit comprising setting up a path from said R.F. output to extract a CDMA signal and not to extract other signals.

38. The method of claim 26, wherein said base station comprises one R.F. transmit output and two R.F. receive inputs.

39. The method according to claim 26, further comprising providing antenna control for azimuthal beam squint and azimuthal beamwidth shaping.

40. The method according to claim 39, wherein said antenna control comprises circuitry for adjusting a main lobe tilt.
